(19) United States
(12) Patent Application Publication
(10) Pub. No.: US 2026/0066018 A1
(43) Pub. Date: Mar. 5, 2026

(54) MEMORY DEVICE INCLUDING DIGITAL TEMPERATURE SENSOR

(71) Applicant: Samsung Electronics Co., Ltd., Suwon-si (KR)

(72) Inventor: Jeil RYU, Suwon-si (KR)

(73) Assignee: Samsung Electronics Co., Ltd., Suwon-si (KR)

(21) Appl. No.: 19/246,938

(22) Filed: Jun. 24, 2025

(30) Foreign Application Priority Data
Aug. 27, 2024 (KR) 10-2024-0115255

(51) Int. Cl. G11C 29/02; G11C 7/10

(52) U.S. Cl. CPC G11C 29/028; G11C 7/1069; G11C 29/022

(57) ABSTRACT

A memory device includes a memory cell array including a plurality of memory cells, and a digital temperature sensor configured to generate a digital temperature code with respect to the memory device. The digital temperature sensor is further configured to generate a sensed temperature code from a temperature of the memory device, and generate the digital temperature code by calibrating the sensed temperature code based on a code ratio and an offset, the code ratio being based on a ratio of a target full code to a difference between a first temperature code corresponding to a first temperature, a second temperature code corresponding to a second temperature, and the offset corresponding to an operation mode of the memory cell array.

### CROSS-REFERENCE TO RELATED APPLICATION

This application is based on and claims priority under 35 U.S.C. § 119 to Korean Patent Application No. 10-2024-0115255, filed on Aug. 27, 2024, in the Korean Intellectual Property Office, the disclosure of which is incorporated by reference herein in its entirety.

### BACKGROUND

Some example embodiments of the inventive concepts relate to a memory device, and more particularly, to a digital temperature sensor, a memory device including the same, and an operating method of the digital temperature sensor.

A memory device may include a memory cell array configured to store data and a digital temperature sensor. A memory device may perform operations on a memory cell array based on a sensed temperature of the memory device sensed by a digital temperature sensor. Accordingly, improving the temperature sensing accuracy of a digital temperature sensor may help to improve the performance and/or reliability of a memory device. However, a temperature code output from a digital temperature sensor may contain code errors due to various factors. Therefore, calibration may be desired to reduce these code errors.

### SUMMARY

Some example embodiments of the inventive concepts provide a memory device including a digital temperature sensor capable of reducing calibration time and/or improve temperature sensing accuracy.

According to some example embodiments of the inventive concepts, there is provided a memory device including a memory cell array including a plurality of memory cells, and a digital temperature sensor configured to generate a digital temperature code with respect to the memory device. The digital temperature sensor is further configured to generate a sensed temperature code from a temperature of the memory device, and generate the digital temperature code by calibrating the sensed temperature code based on a code ratio and an offset, the code ratio being based on a ratio of a target full code to a difference between a first temperature code corresponding to a first temperature, a second temperature code corresponding to a second temperature, and the offset corresponding to an operation mode of the memory cell array.

According to some example embodiments of the inventive concepts, there is provided a memory device including a plurality of memories, wherein each of the plurality of memories includes a memory cell array including a plurality of memory cells, and a digital temperature sensor configured to generate a digital temperature code with respect to the memory device. The digital temperature sensor is further configured to generate a sensed temperature code from temperature of the memory device, and generate the digital temperature code by calibrating the sensed temperature code based on a code ratio and an offset, the code ratio being based on a ratio of a target full code to a difference between a first temperature code corresponding to a first temperature, a second temperature code corresponding to a second temperature, and the offset corresponding to an operation mode of the memory cell array, and the plurality of memories are configured to respectively generate digital temperature codes by using different offsets.

According to some example embodiments of the inventive concepts, there is provided a digital temperature sensor including a voltage generator configured to generate a reference voltage and a temperature voltage, the temperature voltage configured to vary with temperature, an analog-to-digital converter configured to generate a sensed temperature code by performing an analog-to-digital conversion based on the reference voltage and the temperature voltage, and a calibration logic configured to generate a digital temperature code by calibrating the sensed temperature code based on a code ratio and an offset, the code ratio being based on a first temperature code corresponding to a first temperature, a second temperature code corresponding to a second temperature, and a target full code. The calibration logic is further configured to generate a first value by applying the offset to the first temperature code, and generate the code ratio by dividing the target full code by a difference between the second temperature code and the first value, and the target full code corresponds to a difference between a first target code corresponding to the first temperature, and a second target code corresponding to the second temperature.

### BRIEF DESCRIPTION OF THE DRAWINGS

Example embodiments will be more clearly understood from the following detailed description taken in conjunction with the accompanying drawings in which:

FIG. 1 is a block diagram of a memory system according to some example embodiments;

FIG. 2 is a detailed block diagram of a memory device in FIG. 1, according to some example embodiments;

FIG. 3 is a block diagram of a digital temperature sensor according to some example embodiments;

FIG. 4A is a table showing a target code with respect to temperature, according to some example embodiments, and FIG. 4B shows graphs of a digital temperature code with respect to temperature, according to some example embodiments;

FIG. 5A is a table showing a target code with respect to temperature, according to some example embodiments, and FIG. 5B shows graphs of a digital temperature code with respect to temperature, according to some example embodiments;

FIG. 6A shows graphs illustrating calibration in a comparative example, and FIG. 6B shows graphs illustrating calibration according to some example embodiments;

FIG. 7A shows graphs illustrating calibration in a comparative example, and FIG. 7B shows graphs illustrating calibration according to some example embodiments;

FIG. 8 is a flowchart of an operating method of a digital temperature sensor, according to some example embodiments;

FIG. 9 is a flowchart showing a calibration sequence of a digital temperature sensor, according to some example embodiments;

FIG. 10 is a block diagram of a digital temperature sensor according to some example embodiments;

FIG. 11 is a flowchart showing a calibration sequence of a digital temperature sensor, according to some example embodiments;

FIG. 12 is a block diagram of a digital temperature sensor according to some example embodiments;

FIG. 13 is a flowchart showing a calibration sequence of a digital temperature sensor, according to some example embodiments;

FIG. 14 is a block diagram of a digital temperature sensor according to some example embodiments;

FIG. 15 is a table showing a first offset with respect to an operation mode, according to some example embodiments;

FIG. 16 is a flowchart showing a calibration sequence of a digital temperature sensor, according to some example embodiments;

FIGS. 17 and 18 are respectively block diagrams of memory systems according to some example embodiments;

FIGS. 19 to 22 are respectively block diagrams of storage devices according to some example embodiments; and

FIG. 23 is a block diagram of a system according to some example embodiments.

### DETAILED DESCRIPTION

Hereinafter, some example embodiments will be described in detail with reference to the accompanying drawings. In the drawings, like reference characters denote like elements, and redundant descriptions thereof will be omitted.

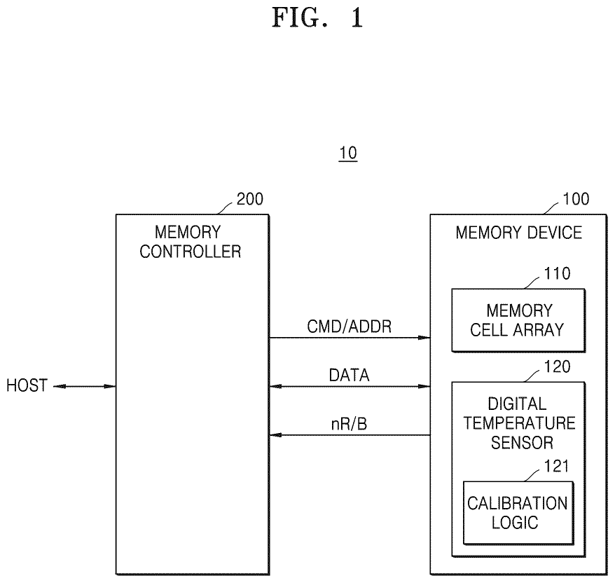

FIG. 1 is a block diagram of a memory system 10 according to some example embodiments.

Referring to FIG. 1, the memory system 10 may include a memory device 100 and a memory controller 200. The memory device 100 may include a memory cell array 110 and a digital temperature sensor 120. In some example embodiments, the memory device 100 may include non-volatile memory, and the memory system 10 may correspond to a storage device. For example, the memory system 10 may correspond to a solid state drive (SSD), but the inventive concepts are not limited thereto.

The memory controller 200 may control the memory device 100 to read data stored in the memory device 100 or program data to the memory device 100, in response to a read or write request from a host. The memory controller 200 may control program, read, and erase operations of the memory device 100 by providing a command/address CMD/ADDR to the memory device 100. Data to be programmed and read data may be exchanged between the memory controller 200 and the memory device 100. The memory controller 200 may also receive a ready/busy output signal nR/B from the memory device 100. The memory controller 200 may determine state information of the memory device 100, based on the ready/busy output signal nR/B.

The memory cell array 110 may include a plurality of memory cells. For example, the memory cells may include NAND flash memory cells. In some example embodiments, the memory cells may include resistive-type memory cells, such as resistive random-access memory (ReRAM) cells, phase-change RAM (PRAM) cells, or magnetic RAM (MRAM) cells. In some example embodiments, the memory cells may include volatile memory cells, such as dynamic RAM (DRAM) cells or static RAM (SRAM) cells.

The digital temperature sensor 120 may generate a digital temperature code with respect to the memory device 100. Specifically, the digital temperature sensor 120 may generate a sensed temperature code from temperature of the memory device 100 and may generate the digital temperature code by calibrating the sensed temperature code. The digital temperature sensor 120 may generate the sensed temperature code based on a temperature voltage varying with temperature. During the operation of the memory device 100, power noise in which a ground voltage level or a power supply voltage level fluctuates may occur, and the temperature voltage may be changed by this power noise, and thus the sensed temperature code may be changed. Accordingly, the temperature sensing accuracy of the digital temperature sensor 120 may decrease, resulting in the decrease in reliability of the memory device 100.

According to some example embodiments, the digital temperature sensor 120 may include a calibration logic 121 calibrating a sensed temperature code. The calibration logic 121 may generate a digital temperature code by calibrating, based on a code ratio, the sensed temperature code. Because the code ratio may be obtained through an operation on digital values, an operation on an analog value, e.g., a temperature value, may not be necessary. Accordingly, an operation speed may be increased. In some example embodiments, the code ratio may correspond to a ratio of a target full code to the difference between a first temperature code corresponding to a first temperature and a second temperature code corresponding to a second temperature. In some example embodiments, the code ratio may correspond to a ratio of the target full code to the difference between the second temperature code and a value obtained by applying an offset to the first temperature code. Here, the target full code may correspond to the difference between a first target code corresponding to the first temperature and a second target code corresponding to the second temperature.

According to some example embodiments, the calibration logic 121 may generate a digital temperature code by calibrating, based on a code ratio and an offset, a sensed temperature code. In some example embodiments, the calibration logic 121 may generate a corrected code ratio by applying an offset to a code ratio and may calibrate a sensed temperature code based on the corrected code ratio. In some example embodiments, the calibration logic 121 may calibrate a sensed temperature code based on a code ratio and apply an offset to the calibrated sensed temperature code. In some example embodiments, the calibration logic 121 may generate a corrected code ratio by applying an offset to a code ratio, calibrate a sensed temperature code based on the corrected code ratio, and additionally apply an offset to the calibrated sensed temperature code.

In some example embodiments, an offset may include a noise offset for compensating for power noise. Specifically, the calibration logic 121 may selectively apply a noise offset to calibration, according to an operation mode of the memory cell array 110. For example, when an operation mode of the memory cell array 110 is an erase mode or a program mode, the digital temperature sensor 120 may calibrate a sensed temperature code based on a code ratio. For example, when an operation mode of the memory cell array 110 is a read mode, the digital temperature sensor 120 may calibrate a sensed temperature code, based on a code ratio and a noise offset.

In some example embodiments, an offset may include noise offsets having different values according to operation modes of the memory cell array 110. For example, noise offsets may include a first noise offset corresponding to the erase mode, a second noise offset corresponding to the program mode, and a third noise offset corresponding to the read mode. The third noise offset may be greater than the first noise offset or the second noise offset. This is described with reference to FIGS. 14 to 16 below. In some example embodiments, the digital temperature sensor 120 may generate a digital temperature code by further calibrating the sensed temperature code based on a user offset defined by a user.

The memory device 100 may transmit state information thereof to the memory controller 200 through the ready/busy output signal nR/B. When the memory device 100 is in a busy state (e.g., when internal operations of the memory device 100 are being performed), the memory device 100 may transmit, to the memory controller 200, the ready/busy output signal nR/B indicating the busy state. When the memory device 100 is in a ready state (e.g., when internal operations of the memory device 100 are not performed or have been completely performed), the memory device 100 may transmit, to the memory controller 200, the ready/busy output signal nR/B indicating the ready state. For example, while the memory device 100 is reading data from the memory cell array 110 in response to a read command, the memory device 100 may transmit, to the memory controller 200, the ready/busy output signal nR/B indicating the busy state (e.g., a low level). For example, while the memory device 100 is programming data to the memory cell array 110 in response to a program command, the memory device 100 may transmit, to the memory controller 200, the ready/busy output signal nR/B indicating the busy state.

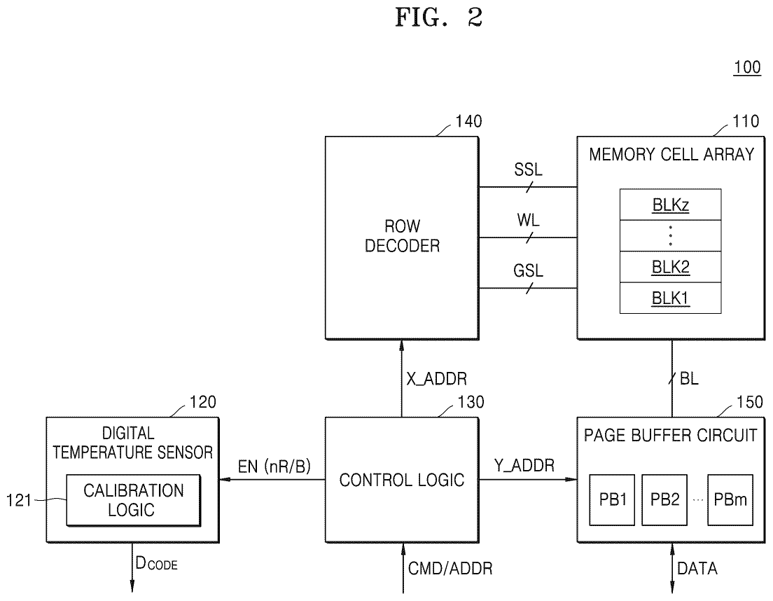

FIG. 2 is a detailed block diagram of the memory device 100 in FIG. 1, according to some example embodiments.

Referring to FIG. 2, the memory device 100 may include the memory cell array 110, the digital temperature sensor 120, a control logic 130, a row decoder 140, and a page buffer circuit 150. The memory cell array 110 may include a plurality of memory blocks BLK1 to BLKz (where “z” is a positive integer). Each of the memory blocks BLK1 to BLKz may include a plurality of pages. Each of the pages may include a plurality of memory cells. For example, a block may be an erase unit and a page may be a write/read unit. The memory cell array 110 may be connected to the row decoder 140 through a plurality of word lines WL, a plurality of string select lines SSL, and a plurality of ground select lines GSL and connected to the page buffer circuit 150 through a plurality of bit lines BL.

In some example embodiments, the memory cell array 110 may include a three-dimensional (3D) memory cell array, which may include a plurality of cell strings or NAND strings. Each of the cell strings may include memory cells respectively connected to word lines, which are vertically stacked on a substrate. The disclosures of U.S. Pat. Nos. 7,679,133, 8,553,466, 8,654,587, 8,559,235, and U.S. Patent Application No. 2011/0233648 are incorporated herein in their entirety by reference.

Based on the command/address CMD/ADDR from the memory controller 200, the control logic 130 may output various control signals for writing data to the memory cell array 110 or reading data from the memory cell array 110. Accordingly, the control logic 130 may generally control various operations of the memory device 100. Specifically, the control logic 130 may provide a row address X_ADDR to the row decoder 140 and a column address Y_ADDR to the page buffer circuit 150. The control logic 130 may also generate the ready/busy output signal nR/B indicating the state of the memory device 100 and provide the ready/busy output signal nR/B to the memory controller 200.

The digital temperature sensor 120 may generate a digital temperature code D_{CODE} by performing a temperature sensing operation, in response to an enable signal EN received from the control logic 130. In some example embodiments, the enable signal EN may include the ready/busy output signal nR/B. For example, in a standby period in which the ready/busy output signal nR/B is at a logic high level, the memory device 100 may not perform an internal operation. In this standby period, the digital temperature sensor 120 may not perform a temperature sensing operation but may be in the ready state. For example, when the ready/busy output signal nR/B transits from the logic high level to a logic low level, the digital temperature sensor 120 may start a temperature sensing operation. For example, in an operation period in which the ready/busy output signal nR/B is at a logic low level, the memory device 100 may perform an erase, a program, or a read operation. In this operation period, the digital temperature sensor 120 may sense temperature and generate a sensed temperature code, and the calibration logic 121 may generate the digital temperature code D_{CODE} by calibrating the sensed temperature code.

In response to the row address X_ADDR, the row decoder 140 may select one of the word lines WL and one of the string select lines SSL. For example, in a program operation, the row decoder 140 may apply a program voltage to a selected word line in a program execution period and a program verify voltage to the selected word line in a program verify period. The page buffer circuit 150 may select at least one of the bit lines BL in response to the column address Y_ADDR. The page buffer circuit 150 may operate as a write driver or a sense amplifier according to an operation mode.

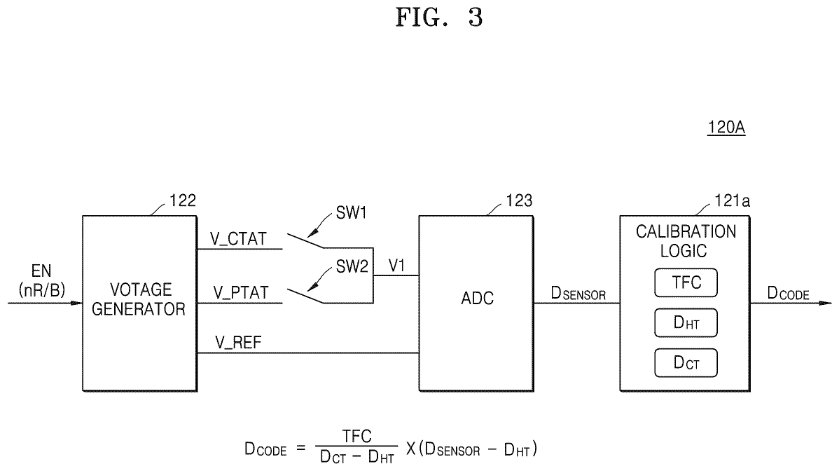

FIG. 3 is a block diagram of a digital temperature sensor 120A according to some example embodiments. Referring to FIG. 3, the digital temperature sensor 120A may include a voltage generator 122, an analog-to-digital converter (ADC) 123, and a calibration logic 121a. The digital temperature sensor 120A corresponds to an example implementation of the digital temperature sensor 120 in FIG. 1. The descriptions made with reference to FIGS. 1 and 2 above may also be applied to some example embodiments.

The voltage generator 122 may generate a first temperature voltage V_CTAT and/or a second temperature voltage V_PTAT in response to the enable signal EN, e.g., the ready/busy output signal nR/B. However, the inventive concepts are not limited thereto. In some example embodiments, the memory controller 200 may transmit a temperature measurement command to the memory device 100, and the voltage generator 122 may generate the first temperature voltage V_CTAT and/or the second temperature voltage V_PTAT in response to the temperature measurement command.

The first temperature voltage V_CTAT may correspond to the temperature of the memory device 100 and may have a voltage level decreasing as temperature increasing. Here, complementary to absolute temperature (CTAT) may represent a component that is inversely proportional to temperature. The second temperature voltage V_PTAT may correspond to the temperature of the memory device 100 and may have a voltage level increasing as temperature increasing. Here, proportional to absolute temperature (PTAT) may represent a component that is proportional to temperature. For example, the voltage generator 122 may include a transistor, which has a threshold voltage varying with temperature, or a variable resistor, which has a resistance value varying with temperature, and thus generate the first temperature voltage V_CTAT and/or the second temperature voltage V_PTAT.

The voltage generator 122 may also generate a reference voltage V_REF in response to the enable signal EN, e.g., the ready/busy output signal nR/B. The reference voltage V_REF may have a constant voltage level regardless of the temperature of the memory device 100. For example, the voltage generator 122 may include a bandgap voltage generation circuit having a constant potential regardless of the change of temperature.

A first switch SW1 may be between the voltage generator 122 and the ADC 123. When the first switch SW1 is turned on, the first temperature voltage V_CTAT may be provided to the ADC 123 as a temperature voltage V1. A second switch SW2 may be between the voltage generator 122 and the ADC 123. When the second switch SW2 is turned on, the second temperature voltage V_PTAT may be provided to the ADC 123 as the temperature voltage V1. For example, the control logic 130 may control the first and second switches SW1 and SW2.

The ADC 123 may generate a sensed temperature code D_{SENSOR} corresponding to temperature. Specifically, the ADC 123 may receive the temperature voltage V1 and the reference voltage V_REF from the voltage generator 122 and may generate the sensed temperature code D_{SENSOR}, based on the temperature voltage V1 and the reference voltage V_REF. For example, the ADC 123 may generate the sensed temperature code D_{SENSOR} that is a digital value by performing analog-to-digital conversion on the temperature voltage V1 and the reference voltage V_REF that are analog values.

The calibration logic 121a may generate the digital temperature code D_{CODE} by calibrating the sensed temperature code D_{SENSOR}. Because of an error occurring when the voltage generator 122 generates the first temperature voltage V_CTAT, the second temperature voltage V_PTAT, or the reference voltage V_REF, an error occurring during the analog-to-digital conversion by the ADC 123, and/or the like, the same sensed temperature code D_{SENSOR} may not be output with respect to the same temperature. Accordingly, the calibration logic 121a may calibrate the sensed temperature code D_{SENSOR} to compensate for the errors.

The calibration logic 121a may store a first temperature code D_{HT} corresponding to the first temperature, a second temperature code D_{CT} corresponding to the second temperature, and a target full code TFC. For example, the first temperature code D_{HT}, the second temperature code D_{CT}, and the target full code TFC may be stored in advance during a test operation. For example, the first temperature code D_{HT} and the second temperature code D_{CT} may be generated in a test operation, and the target full code TFC may be predefined during the mass production of memory devices 100. For example, the calibration logic 121a may include a register that stores the first temperature code D_{HT}, the second temperature code D_{CT}, and the target full code TFC. For example, the first temperature code D_{HT}, the second temperature code D_{CT}, and the target full code TFC may be stored using a fuse or an electronic-fuse (e-fuse).

The calibration logic 121a may determine a code ratio from a ratio of the target full code TFC to the difference between the first temperature code D_{HT} and the second temperature code D_{CT} and may generate the digital temperature code D_{CODE} by multiplying a value, which is obtained by subtracting the first temperature code D_{HT} from the sensed temperature code D_{SENSOR}, by the code ratio. The calibration logic 121a may generate the digital temperature code D_{CODE} by using Equation 1.

$${D}_{CODE} = \frac{TFC}{{D}_{CT} - {D}_{HT}} \times ( {D}_{SENSOR} - {D}_{HT} ) . \qquad [ Equation 1 ]$$

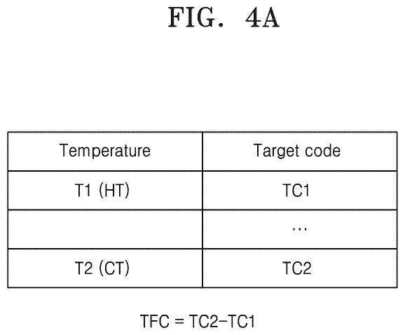

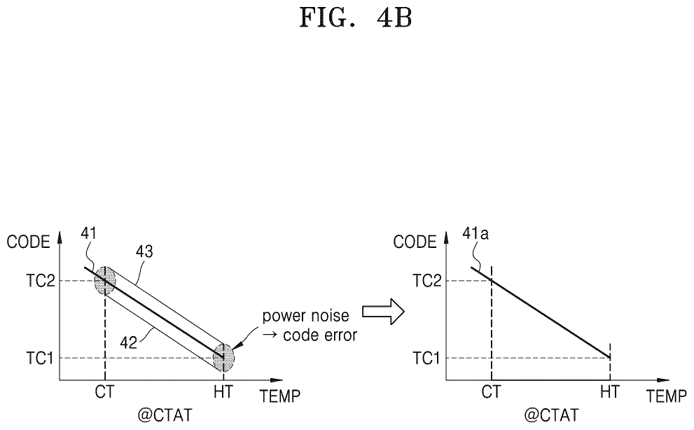

FIG. 4A is a table showing a target code with respect to temperature, according to some example embodiments. FIG. 4B shows graphs of a digital temperature code with respect to temperature, according to some example embodiments.

Referring to FIGS. 3 to 4B, the digital temperature sensor 120A may sense temperature between a first temperature T1 and a second temperature T2. For example, the digital temperature sensor 120A may sense temperature based on the first temperature voltage V_CTAT, which has a voltage level decreasing as temperature increasing. For example, the first temperature T1 may correspond to a hot temperature HT, and the second temperature T2 may correspond to a cold temperature CT. For example, the first temperature T1 may be 125° C. and the second temperature T2 may be −40° C. For example, the digital temperature sensor 120A may provide a sensed result with respect to a temperature range between the first temperature T1 and the second temperature T2, e.g., between 125° C. and −40° C. In the disclosure, the term “hot temperature” may be used interchangeably with the term “high temperature”, and the term “cold temperature” may be used interchangeably with the term “low temperature”.

A first target code TCI corresponding to the first temperature T1 and a second target code TC2 corresponding to the second temperature T2 may be preset. As described above, the table showing a target code with respect to temperature may be stored in the memory device 100 or the memory controller 200 in advance. For example, the memory cell array 110 may store a table showing a target code with respect to temperature. When the operation of the memory device 100 starts, the table stored in the memory cell array 110 may be loaded to the calibration logic 121a.

In this case, the target full code TFC may be generated from the difference between the first target code TC1 and the second target code TC2 (e.g., TFC=TC2−TC1). For example, the first target code TC1 and the second target code TC2 may be respectively set to 584 and 3196. In this case, the target full code TFC may be generated as 2612 (e.g., TC2−TC1=3196−584). For example, the greater the target full code TFC, the higher the temperature sensing resolution. The less the target full code TFC, the lower the temperature sensing resolution.

The memory device 100 may receive a power supply voltage and/or a ground voltage through a chip pad and may perform an erase operation, a program operation, or a read operation based on the power supply voltage and/or the ground voltage. The memory device 100 may start operation in response to the command/address CMD/ADDR received from the memory controller 200. At the start of the operation, power noise may occur due to a change in the power supply voltage and/or the ground voltage.

Because of the power noise, the voltage level of the first temperature voltage V_CTAT and/or the reference voltage V_REF, which are generated by the voltage generator 122, may fluctuate. The sensed temperature code D_{SENSOR} generated by the ADC 123 may hereby change, and accordingly, a code error may occur. Because of the code error, temperature codes 42 and 43 may not match a target code 41. However, according to some example embodiments, the calibration logic 121a may remove power noise by calibrating a sensed temperature code, as shown in Equation 1. Accordingly, a digital temperature code 41a with respect to temperature generated by the digital temperature sensor 120A may be substantially similar to the target code 41.

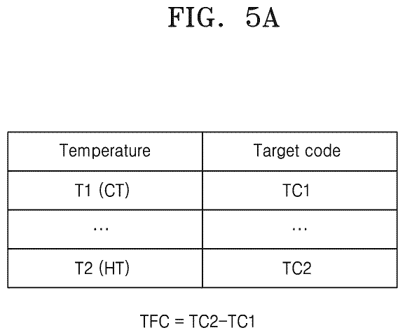

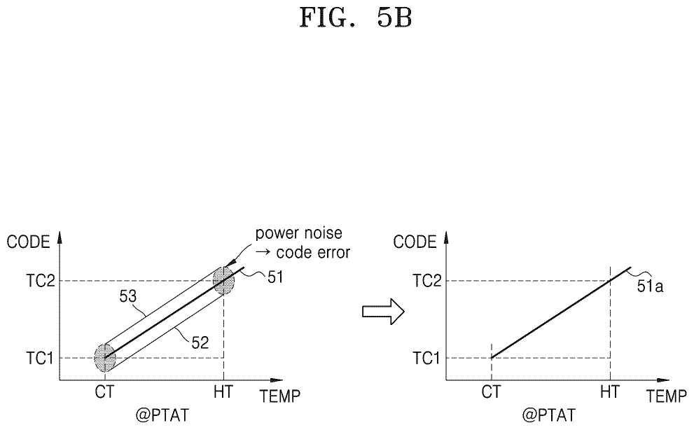

FIG. 5A is a table showing a target code with respect to temperature, according to some example embodiments. FIG. 5B shows graphs of a digital temperature code with respect to temperature, according to some example embodiments.

Referring to FIGS. 3, 5A, and 5B, the digital temperature sensor 120A may sense temperature between the first temperature T1 and the second temperature T2. For example, the digital temperature sensor 120A may sense temperature based on the second temperature voltage V_PTAT, which has a voltage level increasing as temperature increasing. For example, the first temperature T1 may correspond to the cold temperature CT, and the second temperature T2 may correspond to the hot temperature HT. For example, the first temperature T1 may be −40° C. and the second temperature T2 may be 125° C. For example, the digital temperature sensor 120A may provide a sensed result with respect to temperature between the first temperature T1 and the second temperature T2, e.g., between −40° C. and 125° C.

The first target code TC1 corresponding to the first temperature T1 and the second target code TC2 corresponding to the second temperature T2 may be preset. In this case, the target full code TFC may be generated from the difference between the first target code TC1 and the second target code TC2 (e.g., TFC=TC2−TC1). For example, the first target code TC1 and the second target code TC2 may be respectively set to 584 and 3196. In this case, the target full code TFC may be generated as 2612 (e.g., TC2−TC1=3196−584).

Because of the power noise described above, the voltage level of the second temperature voltage V_PTAT and/or the reference voltage V_REF, which are generated by the voltage generator 122, may fluctuate. The sensed temperature code D_{SENSOR} generated by the ADC 123 may hereby change, and accordingly, a code error may occur. Because of the code error, temperature codes 52 and 53 may not match a target code 51. However, according to some example embodiments, the calibration logic 121a may remove power noise by calibrating a sensed temperature code, as shown in Equation 1. Accordingly, a digital temperature code 51a with respect to temperature generated by the digital temperature sensor 120A may be substantially similar to the target code 51.

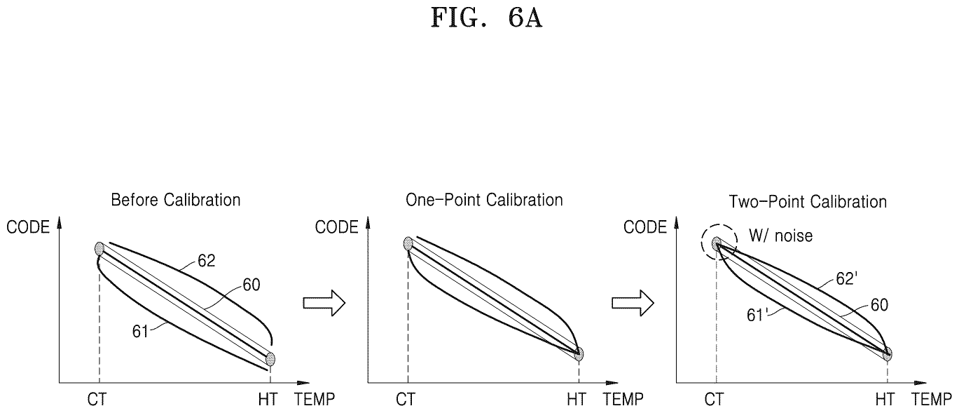

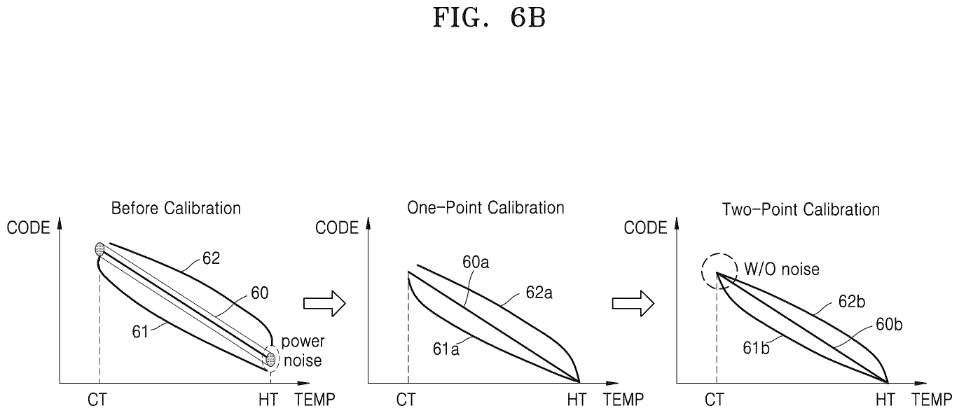

FIG. 6A shows graphs illustrating calibration in a comparative example. FIG. 6B shows graphs illustrating calibration according to some example embodiments.

Referring to FIG. 6A, the horizontal axis of the graph is temperature TEMP and the vertical axis of the graph is a temperature code CODE. Before calibration, the temperature code CODE may have significant code error due to power noise. For example, an ideal code or a target code 60 and real codes or sensing codes 61 and 62 may all have significant code error due to power noise and thus have a thick graph shape. One-point calibration may be performed to reduce code error at the high temperature HT. Subsequently, two-point calibration may be performed to reduce code error at the low temperature CT. However, despite the two-point calibration, there is still power noise in the target code 60 and sensing codes 61′ and 62′, so temperature sensing accuracy may be low.

Referring to FIG. 6B, according to some example embodiments, code error occurring in the temperature code CODE due to power noise may be reduced through calibration, and accordingly, temperature sensing accuracy may be improved. Before calibration, the target code 60 may have significant code error due to power noise, and the real codes or sensing codes 61 and 62 may also have significant code error. By removing the power noise from the target code 60, specifically, the calibration logic 121 may generate a temperature code 60a through one-point calibration and a temperature code 60b through two-point calibration. Accordingly, code error in the temperature code 60b may significantly decrease, so the temperature code 60b may have a thin graph shape.

For example, when one-point calibration, in which calibration is performed at the high temperature HT, is performed, sensing codes 61a and 62a having reduced code error at the high temperature HT may be generated. For example, when two-point calibration, in which calibration is performed at the low temperature CT, is performed, sensing codes 61b and 62b having reduced code error at the low temperature CT may be generated. Accordingly, code error in the sensing codes 61b and 62b may significantly decrease, so the sensing codes 61b and 62b may have a thin graph shape. As described above, noise may be removed from a temperature code through calibration based on a code operation.

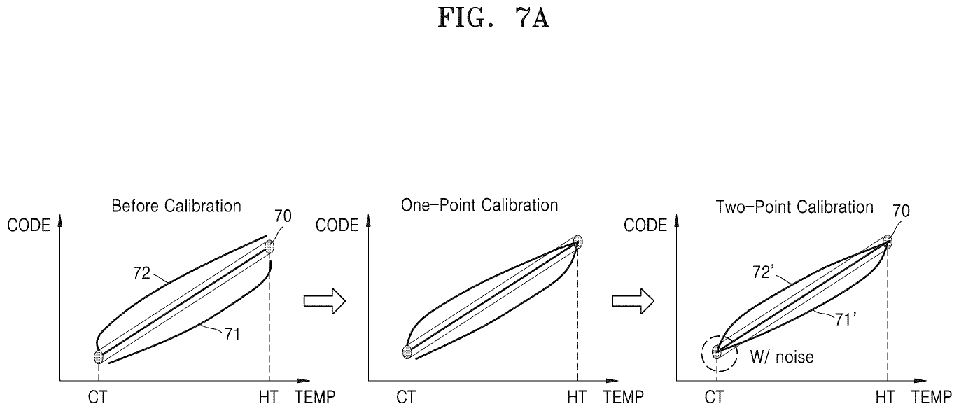

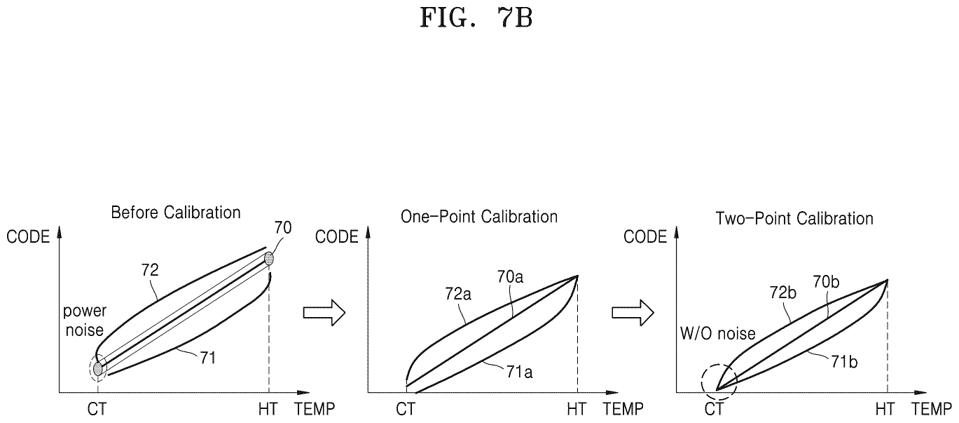

FIG. 7A shows graphs illustrating calibration in a comparative example. FIG. 7B shows graphs illustrating calibration according to some example embodiments.

Referring to FIG. 7A, the horizontal axis of the graph is temperature TEMP and the vertical axis of the graph is a temperature code CODE. Before calibration, the temperature code CODE may have significant code error due to power noise. For example, an ideal code or a target code 70 and real codes or sensing codes 71 and 72 may all have significant code error due to power noise and thus have a thick graph shape. One-point calibration may be performed to reduce code error at the high temperature HT. Subsequently, two-point calibration may be performed to reduce code error at the low temperature CT. However, despite the two-point calibration, there is still power noise in the target code 70 and sensing codes 71′ and 72′, so temperature sensing accuracy may be low.

Referring to FIG. 7B, according to some example embodiments, code error occurring in the temperature code CODE due to power noise may be reduced through calibration, and accordingly, temperature sensing accuracy may be improved. Before calibration, the target code 70 may have significant code error due to power noise, and the real codes or sensing codes 71 and 72 may also have significant code error. By removing the power noise from the target code 70, specifically, the calibration logic 121 may generate a temperature code 70a through one-point calibration and a temperature code 70b through two-point calibration. Accordingly, code error in the temperature code 70b may significantly decrease, so the temperature code 70b may have a thin graph shape.

For example, when one-point calibration, in which calibration is performed at the high temperature HT, is performed, sensing codes 71a and 72a having reduced code error at the high temperature HT may be generated. For example, when two-point calibration, in which calibration is performed at the low temperature CT, is performed, sensing codes 71b and 72b having reduced code error at the low temperature CT may be generated. Accordingly, code error in the sensing codes 71b and 72b may significantly decrease, so the sensing codes 71b and 72b may have a thin graph shape. As described above, noise may be removed from a temperature code through calibration based on a code operation.

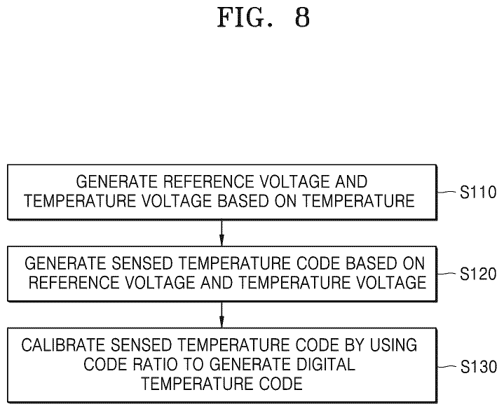

FIG. 8 is a flowchart of an operating method of a digital temperature sensor, according to some example embodiments.

Referring to FIG. 8, the operating method may be performed by the digital temperature sensor 120A of FIG. 3. The reference voltage V_REF and the temperature voltage V1 based on temperature may be generated in operation S110. For example, the digital temperature sensor 120A may perform operation S110 in response to the enable signal EN. The digital temperature sensor 120A may generate the sensed temperature code D_{SENSOR}, based on the reference voltage V_REF and the temperature voltage V1 in operation S120. The digital temperature sensor 120A may calibrate the sensed temperature code D_{SENSOR} by using a code ratio to generate the digital temperature code D_{CODE} in operation S130. For example, the digital temperature sensor 120A may calibrate the sensed temperature code D_{SENSOR} based on Equation 1.

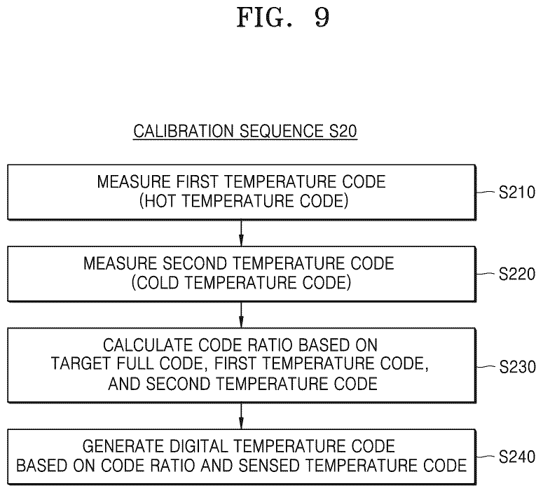

FIG. 9 is a flowchart showing a calibration sequence S20 of a digital temperature sensor, according to some example embodiments. Referring to FIG. 9, for example, the calibration sequence S20 may correspond to an example implementation of operation S130 in FIG. 8. For example, the calibration sequence S20 may be performed by the calibration logic 121a in FIG. 3.

The first temperature code D_{HT} may be measured in operation S210. For example, the first temperature code D_{HT} may correspond to a high temperature code and may be generated based on a temperature voltage measured at a high temperature. For example, the first temperature code D_{HT} may be stored in the calibration logic 121a by using a fuse or an e-fuse. The second temperature code D_{CT} may be measured in operation S220. For example, the second temperature code D_{CT} may correspond to a low temperature code and may be generated based on a temperature voltage measured at a low temperature. For example, the second temperature code D_{CT} may be stored in the calibration logic 121a by using a fuse or an e-fusc.

A code ratio may be calculated based on the target full code TFC, the first temperature code D_{HT}, and the second temperature code D_{CT} in operation S230. For example, the calibration logic 121a may calculate the code ratio by dividing the target full code TFC by the difference between the first temperature code D_{HT} and the second temperature code D_{CT}. The digital temperature code D_{CODE} may be generated based on the code ratio and the sensed temperature code D_{SENSOR} in operation S240. For example, the calibration logic 121a may generate the digital temperature code D_{CODE} by multiplying the difference between the sensed temperature code D_{SENSOR} and the first temperature code D_{HT} by the code ratio.

FIG. 10 is a block diagram of a digital temperature sensor 120B according to some example embodiments. Referring to FIG. 10, the digital temperature sensor 120B may include the voltage generator 122, the ADC 123, and a calibration logic 121b. The digital temperature sensor 120B corresponds to an example modification of the digital temperature sensor 120A of FIG. 3. The descriptions made with reference to FIGS. 3 to 8 above may also be applied to some example embodiments. The differences between the digital temperature sensor 120B and the digital temperature sensor 120A of FIG. 3 are mainly described below.

The calibration logic 121b may generate the digital temperature code D_{CODE} by calibrating the sensed temperature code D_{SENSOR}. The calibration logic 121b may store the first temperature code D_{HT} corresponding to the first temperature, the second temperature code D_{CT} corresponding to the second temperature, the target full code TFC, and a first offset α. For example, the first temperature code D_{HT}, the second temperature code D_{CT}, the target full code TFC, and the first offset α may be stored in advance during a test operation. For example, the first temperature code D_{HT} and the second temperature code D_{CT} may be generated in a test operation, and the target full code TFC may be predefined during the mass production of memory devices 100. For example, the calibration logic 121b may include a register that stores the first temperature code D_{HT}, the second temperature code D_{CT}, the target full code TFC, and the first offset α. For example, the first temperature code D_{HT}, the second temperature code D_{CT}, the target full code TFC, and first offset α may be stored using a fuse or an e-fusc.

The calibration logic 121b may generate a first value by applying the first offset α to the first temperature code D_{HT} and determine a code ratio from a ratio of the target full code TFC to the difference between the first value and the second temperature code D_{CT}. Subsequently, the calibration logic 121b may generate a second value by subtracting the first value from the sensed temperature code D_{SENSOR} and generate the digital temperature code D_{CODE} by multiplying the second value by the code ratio. The calibration logic 121b may generate the digital temperature code D_{CODE} by using Equation 2.

$${D}_{CODE} = \frac{TFC}{{D}_{CT} - ( {D}_{HT} \pm a )} \times ( {D}_{SENSOR} - ( {D}_{HT} \pm α ) ) . \qquad [ Equation 2 ]$$

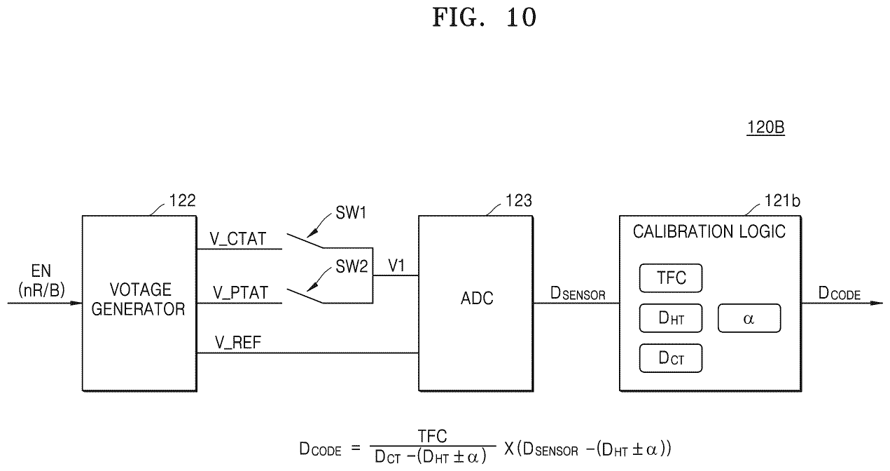

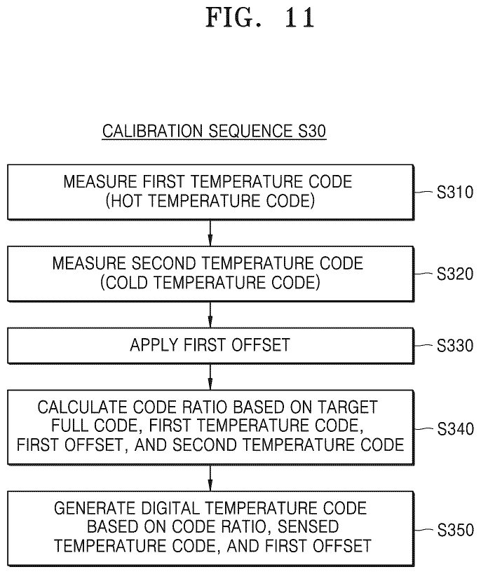

FIG. 11 is a flowchart showing a calibration sequence S30 of a digital temperature sensor, according to some example embodiments. Referring to FIG. 11, for example, the calibration sequence S30 may correspond to an example implementation of operation S130 in FIG. 8 and an example modification of the calibration sequence S20 of FIG. 9. For example, the calibration sequence S30 may be performed by the calibration logic 121b in FIG. 10.

The first temperature code D_{HT} may be measured in operation S310. For example, the first temperature code D_{HT} may correspond to a high temperature code and may be generated based on a temperature voltage measured at a high temperature. The second temperature code D_{CT} may be measured in operation S320. For example, the second temperature code D_{CT} may correspond to a low temperature code and may be generated based on a temperature voltage measured at a low temperature. The first offset α may be applied in operation S330. Here, the first offset α may correspond to a noise offset and may have a different value according to an operation mode.

A code ratio may be calculated based on the target full code TFC, the first temperature code D_{HT}, the second temperature code D_{CT}, and the first offset α in operation S340. For example, the calibration logic 121b may generate a first value by applying the first offset α to the first temperature code D_{HT} and calculate the code ratio by dividing the target full code TFC by the difference between the second temperature code D_{CT} and the first value. The digital temperature code D_{CODE} may be generated based on the code ratio, the sensed temperature code D_{SENSOR}, and the first offset in operation S350. For example, the calibration logic 121b may generate the digital temperature code D_{CODE} by multiplying the difference between the sensed temperature code D_{SENSOR} and the first value by the code ratio.

FIG. 12 is a block diagram of a digital temperature sensor 120C according to some example embodiments. Referring to FIG. 12, the digital temperature sensor 120C may include the voltage generator 122, the ADC 123, and a calibration logic 121c. The digital temperature sensor 120C corresponds to an example modification of the digital temperature sensor 120B of FIG. 10. The descriptions made with reference to FIG. 10 above may also be applied to some example embodiments. The differences between the digital temperature sensor 120C and the digital temperature sensor 120B of FIG. 10 are mainly described below.

The calibration logic 121c may generate the digital temperature code D_{CODE} by calibrating the sensed temperature code D_{SENSOR}. The calibration logic 121c may store the first temperature code D_{HT} corresponding to the first temperature, the second temperature code D_{CT} corresponding to the second temperature, the target full code TFC, the first offset α, and a second offset β. For example, the first temperature code D_{HT}, the second temperature code D_{CT}, the target full code TFC, the first offset α, and the second offset β may be stored in advance during a test operation. For example, the first temperature code D_{HT} and the second temperature code D_{CT} may be generated in a test operation, and the target full code TFC may be predefined during the mass production of memory devices 100. For example, the calibration logic 121c may include a register that stores the first temperature code D_{HT}, the second temperature code D_{CT}, the target full code TFC, the first offset α, and the second offset β. For example, the first temperature code D_{HT}, the second temperature code D_{CT}, the target full code TFC, the first offset α, and the second offset β may be stored using a fuse or an e-fuse.

The calibration logic 121c may generate a first value by applying the first offset α to the first temperature code D_{HT} and determine a code ratio from a ratio of the target full code TFC to the difference between the first value and the second temperature code D_{CT}. The calibration logic 121c may multiply the code ratio by a value obtained by subtracting the first value from the sensed temperature code D_{SENSOR} and subsequently apply the second offset β to a result of the multiplication, thereby generating the digital temperature code D_{CODE}. The calibration logic 121c may generate the digital temperature code D_{CODE} by using Equation 3.

$${D}_{CODE} = \frac{TFC}{{D}_{CT} - ( {D}_{HT} \pm a )} \times ( {D}_{SENSOR} - ( {D}_{HT} \pm α ) ) + β . \qquad [ Equation 3 ]$$

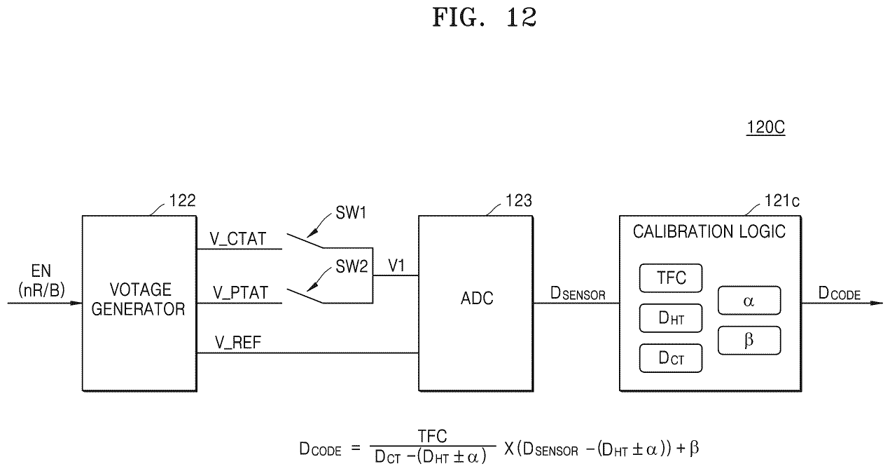

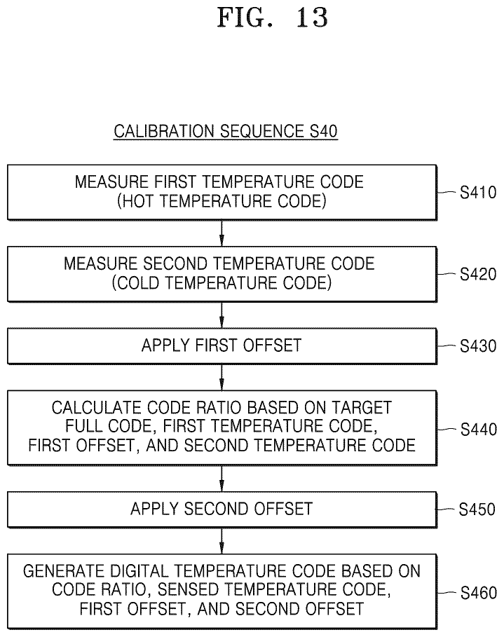

FIG. 13 is a flowchart showing a calibration sequence S40 of a digital temperature sensor, according to some example embodiments. Referring to FIG. 13, for example, the calibration sequence S40 may correspond to an example implementation of operation S130 in FIG. 8 and an example modification of the calibration sequence S30 of FIG. 11. For example, the calibration sequence S40 may be performed by the calibration logic 121c in FIG. 12.

The first temperature code D_{HT} may be measured in operation S410. For example, the first temperature code D_{HT} may correspond to a high temperature code and may be generated based on a temperature voltage measured at a high temperature. The second temperature code D_{CT} may be measured in operation S420. For example, the second temperature code D_{CT} may correspond to a low temperature code and may be generated based on a temperature voltage measured at a low temperature. The first offset α may be applied in operation S430. Here, the first offset α may correspond to a noise offset and may have a different value according to an operation mode.

A code ratio may be calculated based on the target full code TFC, the first temperature code D_{HT}, the second temperature code D_{CT}, and the first offset α in operation S440. For example, the calibration logic 121c may generate a first value by applying the first offset α to the first temperature code D_{HT} and calculate the code ratio by dividing the target full code TFC by the difference between the second temperature code D_{CT} and the first value. The second offset β may be applied in operation S450. Here, the second offset β may correspond to a user offset defined by a user. The digital temperature code D_{CODE} may be generated based on the code ratio, the sensed temperature code D_{SENSOR}, the first offset α, and the second offset β in operation S460. For example, the calibration logic 121c may generate the digital temperature code D_{CODE} by multiplying the difference between the sensed temperature code D_{SENSOR} and the first value by the code ratio and subsequently applying the second offset β to a result of the multiplication.

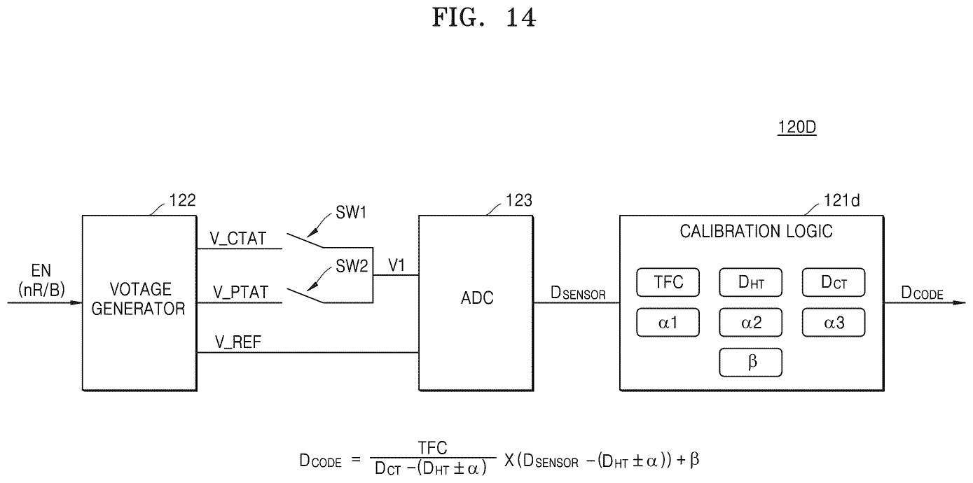

FIG. 14 is a block diagram of a digital temperature sensor 120D according to some example embodiments. FIG. 15 is a table showing a first offset with respect to an operation mode, according to some example embodiments.

Referring to FIGS. 14 and 15, the digital temperature sensor 120D may include the voltage generator 122, the ADC 123, and a calibration logic 121d. The digital temperature sensor 120D corresponds to an example modification of the digital temperature sensor 120C of FIG. 12. The descriptions made with reference to FIG. 12 above may also be applied to some example embodiments. The differences between the digital temperature sensor 120D and the digital temperature sensor 120C of FIG. 12 are mainly described below.

The calibration logic 121d may generate the digital temperature code D_{CODE} by calibrating the sensed temperature code D_{SENSOR}. The calibration logic 121d may store the first temperature code D_{HT} corresponding to the first temperature, the second temperature code D_{CT} corresponding to the second temperature, the target full code TFC, first to third noise offsets α1, α2, α3, and the second offset β. For example, the first temperature code D_{HT}, the second temperature code D_{CT}, the target full code TFC, the first to third noise offsets α1, α2, α3, and the second offset β may be stored in advance during a test operation. For example, the calibration logic 121d may include a register that stores the first temperature code D_{HT}, the second temperature code D_{CT}, the target full code TFC, the first to third noise offsets α1, α2, α3, and the second offset β. For example, the first temperature code D_{HT}, the second temperature code D_{CT}, the target full code TFC, the first to third noise offsets α1, α2, α3, and the second offset β may be stored using a fuse or an e-fuse.

The first to third noise offsets α1, α2, α3 may have different values according to an operation mode of the memory cell array 110. Because an operation time is different according to each operation mode, power noise in which a ground voltage level and/or a power supply voltage level fluctuates may also differ according to each operation mode. For example, a range of fluctuation of the ground voltage level at the start of a read operation may be greater than a range of fluctuation of the ground voltage level at the start of a program operation. Accordingly, during the read operation, power noise may be relatively large, and thus, a code error in a temperature code may also be relatively large.

In some example embodiments, the calibration logic 121d may determine an operation mode of the memory cell array 110, based on the command/address CMD/ADDR received from the memory controller 200, and may select one of the first to third noise offsets α1, α2, α3, based on the determined operation mode. In some example embodiments, the control logic 130 may determine an operation mode of the memory cell array 110, based on the command/address CMD/ADDR received from the memory controller 200, and may transmit a control signal for selecting one of the first to third noise offsets α1, α2, α3 to the calibration logic 121d, based on the determined operation mode. The calibration logic 121d may select one of the first to third noise offsets α1, α2, α3 in response to the control signal.

For example, when an operation mode of a memory cell array is an erase mode, the calibration logic 121d may select the first noise offset α1 and perform calibration based on the first noise offset α1. When an operation mode of a memory cell array is a program mode, the calibration logic 121d may select the second noise offset α2 and perform calibration based on the second noise offset α2. When an operation mode of a memory cell array is a read mode, the calibration logic 121d may select the third noise offset α3 and perform calibration based on the third noise offset α3.

For example, the third noise offset α3 may be greater than the first noise offset α1 or the second noise offset α2. For example, the first noise offset α1 or the second noise offset α2 may be 0. Power noise may be relatively large at the start of an operation, and an erase operation time or a program operation time may be longer than a read operation time. Accordingly, in an erase operation or a program operation, temperature sensing and calibration may be started after a certain time elapses since the ready/busy output signal nR/B transits to a logic low level. In this case, an offset may not be applied during the calibration. Because the read operation time is relatively short, temperature sensing and calibration may need to be carried out right after the ready/busy output signal nR/B transits to the logic low level, and accordingly, an offset may be applied during the calibration.

The calibration logic 121d may select one of the first to third noise offsets α1, α2, α3 as the first offset α according to an operation mode of a memory cell array, may generate the first value by applying the first offset α to the first temperature code D_{HT}, and may determine a code ratio from a ratio of the target full code TFC to the difference between the second temperature code D_{CT} and the first value. The calibration logic 121d may generate the digital temperature code D_{CODE} by multiplying the code ratio by a value obtained by subtracting the first value from the sensed temperature code D_{SENSOR} and subsequently applying the second offset β to a result of the multiplication. The calibration logic 121d may generate the digital temperature code D_{CODE} by using Equation 3.

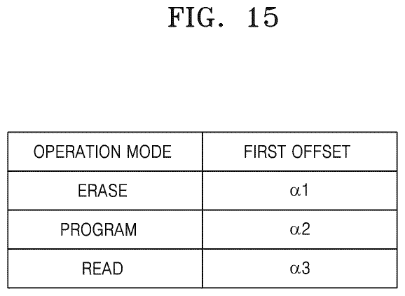

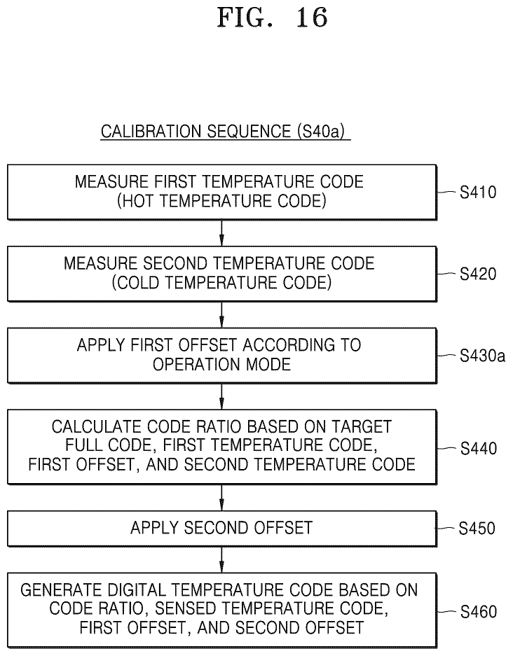

FIG. 16 is a flowchart showing a calibration sequence S40a of a digital temperature sensor, according to some example embodiments. Referring to FIG. 16, for example, the calibration sequence S40a may correspond to an example implementation of operation S130 in FIG. 8 and an example modification of the calibration sequence S40 of FIG. 13. For example, the calibration sequence S40a may be performed by the calibration logic 121d in FIG. 15.

The first temperature code D_{HT} may be measured in operation S410. For example, the first temperature code D_{HT} may correspond to a high temperature code and may be generated based on a temperature voltage measured at a high temperature. The second temperature code D_{CT} may be measured in operation S420. For example, the second temperature code D_{CT} may correspond to a low temperature code and may be generated based on a temperature voltage measured at a low temperature. The first offset α may be applied according to an operation mode in operation S430a. Here, the first offset α may correspond to a noise offset. The calibration logic 121d may select one of the first to third noise offsets α1, α2, α3 as the first offset α according to an operation mode.

A code ratio may be calculated based on the target full code TFC, the first temperature code D_{HT}, the second temperature code D_{CT}, and the first offset α in operation S440. For example, the calibration logic 121d may generate a first value by applying the first offset α to the first temperature code D_{HT} and calculate the code ratio by dividing the target full code TFC by the difference between the second temperature code D_{CT} and the first value. The second offset β may be applied in operation S450. Here, the second offset β may correspond to a user offset defined by a user. The digital temperature code D_{CODE} may be generated based on the code ratio, the sensed temperature code D_{SENSOR}, the first offset α, and the second offset β in operation S460. For example, the calibration logic 121d may generate the digital temperature code D_{CODE} by multiplying the difference between the sensed temperature code D_{SENSOR} and the first value by the code ratio and subsequently applying the second offset β to a result of the multiplication.

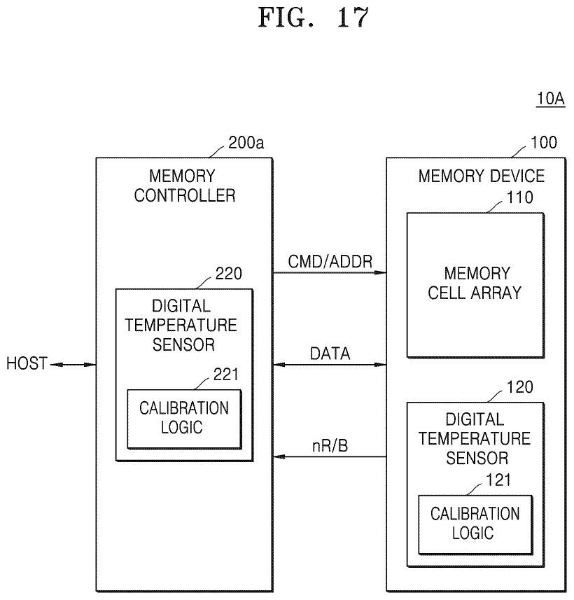

FIG. 17 is a block diagram of a memory system 10A according to some example embodiments.

Referring to FIG. 17, the memory system 10A may include the memory device 100 and a memory controller 200a. The memory controller 200a may include a digital temperature sensor 220. The memory system 10A may correspond to an example modification of the memory system 10 of FIG. 1, and the memory device 100 may correspond to the memory device 100 in FIG. 1. Thus, the descriptions made above with reference to FIGS. 1 to 16 may also be applied to some example embodiments.

The digital temperature sensor 220 may generate a digital temperature code with respect to the memory controller 200a. Specifically, the digital temperature sensor 220 may generate a sensed temperature code from temperature of the memory controller 200a and may generate the digital temperature code by calibrating the sensed temperature code. The digital temperature sensor 220 may generate the sensed temperature code based on a temperature voltage varying with temperature. During the operation of the memory controller 200a, power noise in which a ground voltage level or a power supply voltage level fluctuates may occur, and the temperature voltage may be changed by this power noise, and thus the sensed temperature code may be changed. Accordingly, accuracy of the sensed temperature code may decrease, resulting in the decrease in reliability of the memory controller 200a and the memory system 10A.

According to some example embodiments, the digital temperature sensor 220 may include a calibration logic 221 calibrating a sensed temperature code. The calibration logic 221 may generate a digital temperature code by calibrating, based on a code ratio, the sensed temperature code. Because the code ratio may be obtained through an operation on digital values, an operation on an analog value, e.g., a temperature value, may not be necessary. Accordingly, an operation speed may be increased. In some example embodiments, the code ratio may correspond to a ratio of a target full code to the difference between a first temperature code corresponding to a first temperature and a second temperature code corresponding to a second temperature. In some example embodiments, the code ratio may correspond to a ratio of the target full code to a value obtained by applying an offset to the difference between the first temperature code and the second temperature code. Here, the target full code may correspond to the difference between a first target code corresponding to the first temperature and a second target code corresponding to the second temperature.

According to some example embodiments, the calibration logic 221 may generate a digital temperature code by calibrating, based on a code ratio and an offset, a sensed temperature code. In some example embodiments, the calibration logic 221 may generate a corrected code ratio by applying an offset to a code ratio and may calibrate a sensed temperature code based on the corrected code ratio. In some example embodiments, the calibration logic 221 may calibrate a sensed temperature code based on a code ratio and apply an offset to the calibrated sensed temperature code. In some example embodiments, the calibration logic 221 may generate a corrected code ratio by applying an offset to a code ratio, calibrate a sensed temperature code based on the corrected code ratio, and additionally apply an offset to the calibrated sensed temperature code.

In some example embodiments, an offset may include a noise offset for compensating for power noise. Specifically, the calibration logic 221 may selectively apply a noise offset to calibration, according to an operating state of the memory controller 200a. For example, the memory controller 200a may control a plurality of memory devices and may include a plurality of processors. In this case, the memory controller 200a may selectively apply a noise offset or change a noise offset value, according to the number of processors in operation, the number of memory devices in operation, or the type of request received from a host. In some example embodiments, the offset may further include a user offset defined by a user. Specifically, the calibration logic 221 may generate a digital temperature code by further calibrating the sensed temperature code based on the user offset.

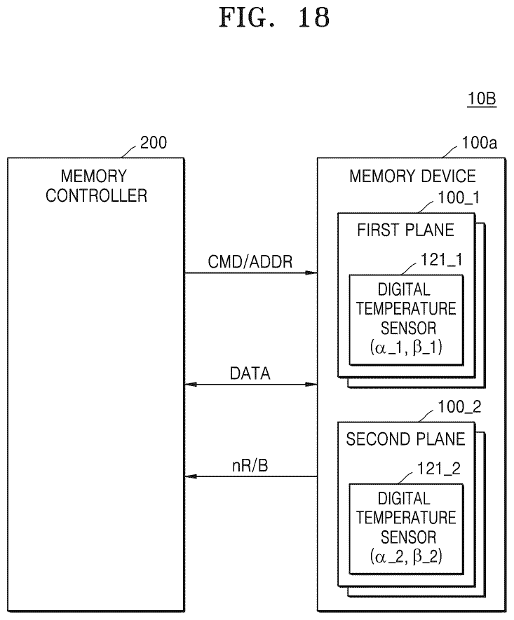

FIG. 18 is a block diagram of a memory system 10B according to some example embodiments.

Referring to FIG. 18, the memory system 10B may include a memory device 100a and the memory controller 200. The memory device 100a may include a plurality of memory planes including a first plane 100_1 and a second plane 100_2. The first and second planes 100_1 and 100_2 may each be a memory unit that may operate independently. For example, the memory device 100a may include at least one memory die. Each memory die may include a plurality of memory planes. Each memory plane may include a plurality of memory blocks. Each memory block may include a plurality of memory cells.

The first plane 100_1 may include a digital temperature sensor 121_1. The digital temperature sensor 121_1 may perform calibration based on a first offset α_1 and a second offset β_1. Specifically, the digital temperature sensor 121_1 may generate a first sensed temperature code from temperature of the first plane 100_1 and generate a first digital temperature code by calibrating the first sensed temperature code based on a code ratio, the first offset α_1, and the second offset β_1. The first offset α_1 may have a different value according to an operation mode of the first plane 100_1. In some example embodiments, the code ratio may correspond to a ratio of a target full code to the difference between a first temperature code and a second temperature code. In some example embodiments, the code ratio may correspond to a ratio of the target full code to the difference between the second temperature code and a value obtained by applying the first offset α_1 to the first temperature code.

The second plane 100_2 may include a digital temperature sensor 121_2. The digital temperature sensor 121_2 may perform calibration based on a first offset α_2 and a second offset ⊕_2. Specifically, the digital temperature sensor 121_2 may generate a second sensed temperature code from temperature of the second plane 100_2 and generate a second digital temperature code by calibrating the second sensed temperature code based on a code ratio, the first offset α_2 and the second offset β_2. The first offset α_2 may have a different value according to an operation mode of the second plane 100_2. In some example embodiments, the code ratio may correspond to a ratio of a target full code to the difference between a first temperature code and a second temperature code. In some example embodiments, the code ratio may correspond to a ratio of the target full code to the difference between the second temperature code and a value obtained by applying the first offset α_2 to the first temperature code.

As described above, the memory device 100a may calibrate a sensed temperature code by respectively applying different noise offsets (e.g., α_1 and α_2) to different planes and respectively applying different user offsets (e.g., β_1and β_2) to different planes. Each of the first and second planes 100_1 and 100_2 may calibrate a sensed temperature code by using a noise offset and/or a user offset, each having a different value according to an operation mode. Furthermore, the memory device 100a may calibrate the sensed temperature code by using a noise offset and/or a user offset, each having a different value according to the number of planes in operation. Accordingly, calibration speed and/or temperature sensing accuracy may be improved.

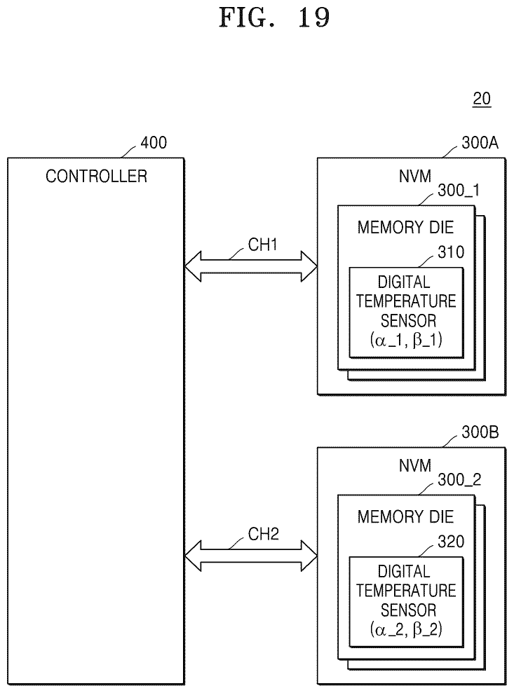

FIG. 19 is a block diagram of a storage device 20 according to some example embodiments.

Referring to FIG. 19, the storage device 20 may include non-volatile memories (NVMs) 300A and 300B and a controller 400. The NVM 300A may communicate with the controller 400 through a first channel CH1. The NVM 300B may communicate with the controller 400 through a second channel CH2. The NVM 300A may include a plurality of memory dies 300_1. The NVM 300B may include a plurality of memory dies 300_2. For example, the NVM 300A and the NVM 300B may each be referred to as a memory package. For example, the memory dies 300_1 may be stacked in a direction perpendicular to a substrate. For example, the memory dies 300_2 may be stacked in a direction perpendicular to a substrate. The memory dies 300_1 and 300_2 may correspond to an example implementation of the memory device 100 or 100a in FIGS. 1 to 18, and the descriptions made with reference to FIGS. 1 to 18 may also be applied to some example embodiments.

Each of the memory dies 300_1 may include a digital temperature sensor 310. The digital temperature sensor 310 may perform calibration based on a first offset α_1 and a second offset β_1. Specifically, the digital temperature sensor 310 may generate a first sensed temperature code from temperature of a memory die 300_1 and generate a first digital temperature code by calibrating the first sensed temperature code based on a code ratio, the first offset α_1, and the second offset β_1. The first offset α_1 may have a different value according to an operation mode of the memory die 300_1. In some example embodiments, the code ratio may correspond to a ratio of a target full code to the difference between a first temperature code and a second temperature code. In some example embodiments, the code ratio may correspond to a ratio of the target full code to the difference between the second temperature code and a value obtained by applying the first offset α_1 to the first temperature code.

Each of the memory dies 300_2 may include a digital temperature sensor 320. The digital temperature sensor 320 may perform calibration based on a first offset α_2 and a second offset β_2. Specifically, the digital temperature sensor 320 may generate a second sensed temperature code from temperature of a memory die 300_2 and generate a second digital temperature code by calibrating the second sensed temperature code based on a code ratio, the first offset α_2, and the second offset β_2. The first offset α_2 may have a different value according to an operation mode of the memory die 300_2. In some example embodiments, the code ratio may correspond to a ratio of a target full code to the difference between a first temperature code and a second temperature code. In some example embodiments, the code ratio may correspond to a ratio of the target full code to the difference between the second temperature code and a value obtained by applying the first offset α_2 to the first temperature code.

In some example embodiments, the controller 400 may transmit a command/address to the NVM 300A and the NVM 300B. For example, the controller 400 may transmit a first command to the NVM 300A through the first channel CHI, and the NVM 300A may transmit the ready/busy output signal nR/B to the controller 400 in response to the first command. When the ready/busy output signal nR/B transits to a logic low level, the digital temperature sensor 310 may perform temperature sensing and calibration. For example, the controller 400 may transmit a second command to the NVM 300B through the second channel CH2, and the NVM 300B may transmit the ready/busy output signal nR/B to the controller 400 in response to the second command. When the ready/busy output signal nR/B transits to a logic low level, the digital temperature sensor 320 may perform temperature sensing and calibration. The first and second commands may include an operation command instructing to erase, program, or read.

In some example embodiments, the controller 400 may transmit a temperature sensing command to the NVM 300A and the NVM 300B. For example, the controller 400 may transmit a first temperature sensing command to the NVM 300A through the first channel CH1, and the digital temperature sensor 310 of the NVM 300A may perform temperature sensing and calibration in response to the first temperature sensing command. For example, the controller 400 may transmit a second temperature sensing command to the NVM 300B through the second channel CH2, and the digital temperature sensor 320 of the NVM 300B may perform temperature sensing and calibration in response to the second temperature sensing command.

As described above, each of the NVM 300A and the NVM 300B may calibrate a sensed temperature code by applying a different noise offset (e.g., α_1 or α_2) to a different memory die and applying a different user offset (e.g., β₁ or β_2) to a different memory die. Each of the memory dies 300_1 and 300_2 may calibrate a sensed temperature code by using a noise offset and/or a user offset, each having a different value according to an operation mode. Accordingly, calibration speed and/or temperature sensing accuracy may be improved.

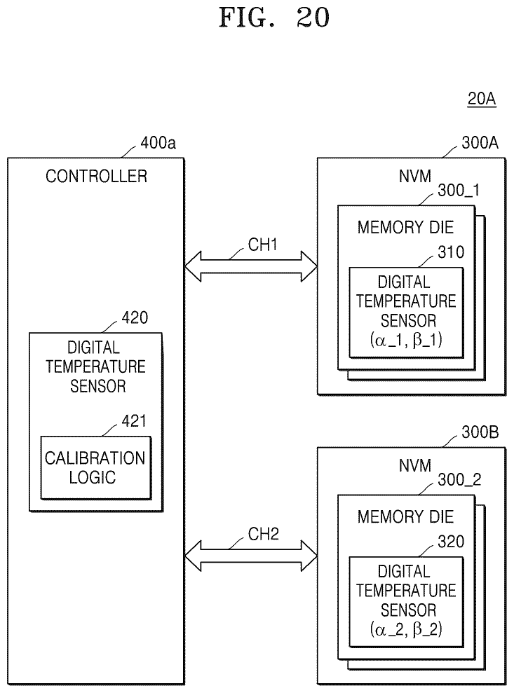

FIG. 20 is a block diagram of a storage device 20A according to some example embodiments.

Referring to FIG. 20, the storage device 20A may include the NVM 300A, the NVM 300B, and a controller 400a. The controller 400a may include a digital temperature sensor 420. The storage device 20A may correspond to an example modification of the storage device 20 of FIG. 19, and the NVM 300A and the NVM 300B may respectively correspond to the NVM 300A and the NVM 300B in FIG. 19. Thus, the descriptions made above with reference to FIG. 19 may also be applied to some example embodiments.

The digital temperature sensor 420 may generate a digital temperature code with respect to the controller 400a. Specifically, the digital temperature sensor 420 may generate a sensed temperature code from temperature of the controller 400a and may generate the digital temperature code by calibrating the sensed temperature code. The digital temperature sensor 420 may include a calibration logic 421 calibrating a sensed temperature code. The calibration logic 421 may generate a digital temperature code by calibrating, based on a code ratio, the sensed temperature code. Because the code ratio may be obtained through an operation on digital values, an operation on an analog value, e.g., a temperature value, may not be necessary. Accordingly, an operation speed may be increased.

According to some example embodiments, the calibration logic 421 may generate a digital temperature code by calibrating, based on a code ratio and an offset, a sensed temperature code. In some example embodiments, the calibration logic 421 may generate a corrected code ratio by applying an offset to a code ratio and may calibrate a sensed temperature code based on the corrected code ratio. In some example embodiments, the calibration logic 421 may calibrate a sensed temperature code based on a code ratio and apply an offset to the calibrated sensed temperature code. In some example embodiments, the calibration logic 421 may generate a corrected code ratio by applying an offset to a code ratio, calibrate a sensed temperature code based on the corrected code ratio, and additionally apply an offset to the calibrated sensed temperature code. In some example embodiments, an offset may include a noise offset for compensating for power noise. Specifically, the calibration logic 421 may selectively apply a noise offset to calibration, according to an operating state of the controller 400a. In some example embodiments, the offset may further include a user offset defined by a user. Specifically, the calibration logic 421 may generate a digital temperature code by further calibrating the sensed temperature code based on the user offset.

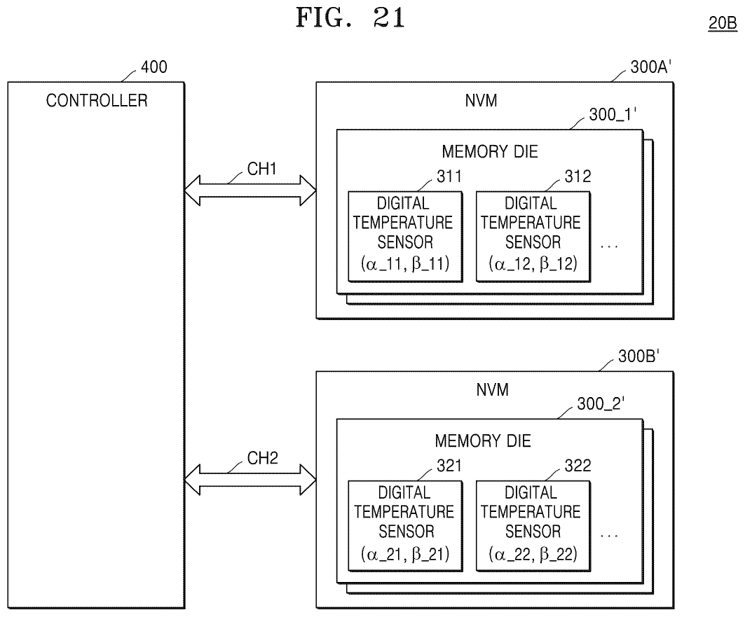

FIG. 21 is a block diagram of a storage device 20B according to some example embodiments.

Referring to FIG. 21, the storage device 20B may include NVM 300A′, NVM 300B′, and the controller 400. The storage device 20B may correspond to an example modification of the storage device 20 of FIG. 19, and the NVM 300A′ and the NVM 300B′ may respectively correspond to the NVM 300A and the NVM 300B in FIG. 19. Thus, the descriptions made above with reference to FIG. 19 may also be applied to some example embodiments.

Each of memory dies 300_1′ may include a plurality of digital temperature sensors 311 and 312. The digital temperature sensor 311 may perform calibration based on a first offset α_11 and a second offset β_11. The digital temperature sensor 312 may perform calibration based on a first offset α_12 and a second offset β_12. For example, the digital temperature sensors 311 and 312 may respectively correspond to a plurality of memory groups, such as a plurality of memory planes or a plurality of memory blocks. Similarly, each of memory dies 300_2′ may include a plurality of digital temperature sensors 321 and 322. The digital temperature sensor 321 may perform calibration based on a first offset α_21 and a second offset β_21. The digital temperature sensor 322 may perform calibration based on a first offset α_22 and a second offset β_22. For example, the digital temperature sensors 321 and 322 may respectively correspond to a plurality of memory groups, such as a plurality of memory planes or a plurality of memory blocks.

As described above, each of the NVM 300A′ and the NVM 300B′ may calibrate a sensed temperature code by applying different noise offsets (e.g., α_11 and α_12) to different memory groups, respectively, in a memory die and applying different user offsets (e.g., β_11 and β_12) to different memory groups, respectively, in the memory die. Each of the memory dies 300_1′ and 300_2′ may calibrate a sensed temperature code by using a noise offset and/or a user offset, each having a different value according to an operation mode. Furthermore, each of the memory dies 300_1′ and 300_2′ may calibrate a sensed temperature code by using a noise offset and/or a user offset, each having a different value according to the number of planes in operation. Accordingly, calibration operation speed and/or temperature sensing accuracy may be improved.

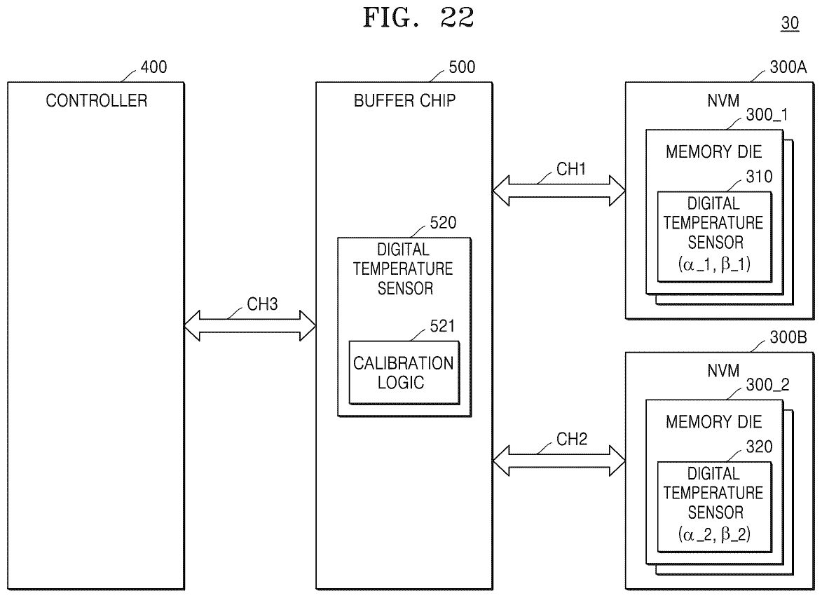

FIG. 22 is a block diagram of a storage device 30 according to some example embodiments.

Referring to FIG. 22, the storage device 30 may include the NVM 300A, the NVM 300B, the controller 400, and a buffer chip 500. The buffer chip 500 may include a digital temperature sensor 520. The NVM 300A may communicate with the buffer chip 500 through the first channel CH1. The NVM 300B may communicate with the buffer chip 500 through the second channel CH2. The buffer chip 500 may communicate with the controller 400 through a third channel CH3. The buffer chip 500 may be connected between the controller 40 and the NVMs 300A and 300B and referred to as a frequency boosting interface (FBI). For example, the NVMs 300A and 300B and the buffer chip 500 may be implemented in a single package. The storage device 30 may correspond to an example modification of the storage device 20 of FIG. 19, and the NVMs 300A and 300B may respectively correspond to the NVMs 300A and 300B in FIG. 19. Thus, the descriptions made above with reference to FIG. 19 may also be applied to some example embodiments.

The digital temperature sensor 520 may generate a digital temperature code for the buffer chip 500. Specifically, the digital temperature sensor 520 may generate a sensed temperature code from temperature of the buffer chip 500 and generate the digital temperature code by calibrating the sensed temperature code. The digital temperature sensor 520 may include a calibration logic 521 calibrating the sensed temperature code. The calibration logic 521 may generate the digital temperature code by calibrating the sensed temperature code based on a code ratio. Because the code ratio may be obtained through an operation on digital values, an operation on an analog value, e.g., a temperature value, may not be necessary. Accordingly, an operation speed may be increased.

According to some example embodiments, the calibration logic 521 may generate a digital temperature code by calibrating, based on a code ratio and an offset, a sensed temperature code. In some example embodiments, the calibration logic 521 may generate a corrected code ratio by applying an offset to a code ratio and may calibrate a sensed temperature code based on the corrected code ratio. In some example embodiments, the calibration logic 521 may calibrate a sensed temperature code based on a code ratio and apply an offset to the calibrated sensed temperature code. In some example embodiments, the calibration logic 521 may generate a corrected code ratio by applying an offset to a code ratio, calibrate a sensed temperature code based on the corrected code ratio, and additionally apply an offset to the calibrated sensed temperature code. In some example embodiments, an offset may include a noise offset for compensating for power noise. Specifically, the calibration logic 521 may selectively use a noise offset according to an operating state of the buffer chip 500. In some example embodiments, the offset may further include a user offset defined by a user. Specifically, the calibration logic 521 may generate a digital temperature code by further calibrating the sensed temperature code based on the user offset.

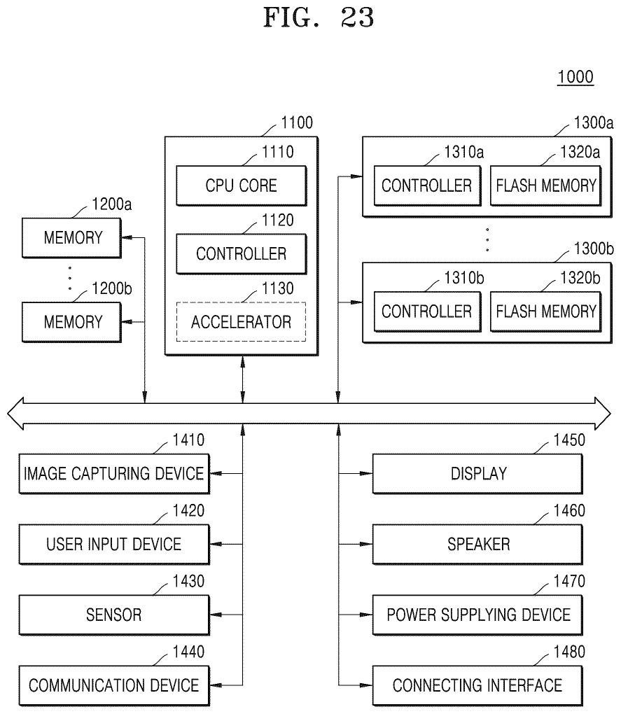

FIG. 23 is a block diagram of a system 1000 according to some example embodiments.

Referring to FIG. 23, a memory system, or a storage device according to some example embodiments may be applied to the system 1000. For example, the system 1000 may basically be a mobile system, such as a mobile phone, a smartphone, a tablet personal computer (PC), a wearable device, a healthcare device, or an Internet of things (IoT) device. However, the system 1000 is not limited thereto and may correspond to a PC, a laptop computer, a server, a media player, or an automotive device like a navigation device.

The system 1000 may include a main processor 1100, memories 1200a and 1200b, and storage devices 1300a and 1300b and may further include at least one selected from the group consisting of an optical input device 1410, a user input device 1420, a sensor 1430, a communication device 1440, a display 1450, a speaker 1460, a power supplying device 1470, and a connecting interface 1480. Each element of the system 1000 may include a digital temperature sensor illustrated in FIGS. 1 to 22. The digital temperature sensor may generate a digital temperature code by calibrating, based on an offset and a code ratio for digital values, a sensed temperature code.

The main processor 1100 may generally control operations of the system 1000, and more particularly, operations of the other elements of the system 1000. The main processor 1100 may include a general-purpose processor, a dedicated processor, or an application processor. The main processor 1100 may include at least one central processing unit (CPU) core 1110 and further include a controller 1120, which controls the memories 1200a and 1200b and/or the storage devices 1300a and 1300b. According to some example embodiments, the main processor 1100 may further include an accelerator 1130, which is a dedicated circuit for high-speed data operations such as artificial intelligence (AI) data operations. The accelerator 1130 may include a graphics processing unit (GPU), a neural processing unit (NPU), and/or a data processing unit (DPU) and may be implemented in a separate chip physically independent from other elements of the main processor 1100. At least one of the main processor 1100, the controller 1120, and the accelerator 1130 may include a digital temperature sensor. The digital temperature sensor may generate a digital temperature code by calibrating, based on an offset and a code ratio for digital values, a sensed temperature code.

The memories 1200a and 1200b may be used as a main memory device of the system 1000 and may include volatile memory, such as SRAM and/or DRAM, or non-volatile memory, such as flash memory, PRAM, and/or ReRAM. The memories 1200a and 1200b may be implemented in the same package as the main processor 1100. The storage devices 1300a and 1300b may include a non-volatile storage device that retains data regardless of power supply and may have a larger capacity than the memories 1200a and 1200b. The storage devices 1300a and 1300b may include storage controllers 1310a and 1310b, respectively, and flash memories 1320a and 1320b, respectively. The flash memory 1320a may store data under control by the storage controller 1310a, and the flash memory 1320b may store data under control by the storage controller 1310b. The flash memories 1320a and 1320b may have a two-dimensional (2D) or 3D vertical NAND (V-NAND) structure or other types of NVM, such as PRAM and/or ReRAM. At least one of the memories 1200a and 1200b and the flash memories 1320a and 1320b may include a digital temperature sensor. The digital temperature sensor may generate a digital temperature code by calibrating, based on an offset and a code ratio for digital values, a sensed temperature code.

The storage devices 1300a and 1300b may be physically separated from the main processor 1100 in the system 1000 or may be implemented in the same package as the main processor 1100. The storage devices 1300a and 1300b may have a form of an SSD or a memory card and may thus be removably coupled to other elements of the system 1000 through an interface, such as the connecting interface 1480, which will be described below. The storage devices 1300a and 1300b may include a device, to which a protocol, such as a UFS standard, an eMMC standard, or an NVM express (NVMe) standard, is applied, but are not necessarily limited thereto.

The optical input device 1410 may capture a still image or a moving image and may include a camera, a camcorder, and/or a webcam. The user input device 1420 may receive various types of data input by a user of the system 1000 and may include a touch pad, a key pad, a keyboard, a mouse, and/or a microphone. The sensor 1430 may sense various types of physical quantities that may be acquired from outside the system 1000 and may convert sensed physical quantities into electrical signals. The communication device 1440 may transmit or receive signals to or from other devices outside the system 1000 according to various communication protocols. The display 1450 and the speaker 1460 may function as output devices that respectively output visual information and auditory information to the user of the system 1000. The power supplying device 1470 may appropriately transform power from a battery (not shown) embedded in the system 1000 and/or an external power supply and may supply transformed power to each element of the system 1000. The connecting interface 1480 may provide a connection between the system 1000 and an external device, which is connected to the system 1000 and may exchange data with the system 1000.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application- specific integrated circuit (ASIC), etc.

While the inventive concepts has been particularly shown and described with reference to embodiments thereof, it will be understood that various changes in form and details may be made therein without departing from the spirit and scope of the following claims.

1. A memory device comprising:
a memory cell array including a plurality of memory cells; and
a digital temperature sensor configured to generate a digital temperature code with respect to the memory device,
wherein the digital temperature sensor is further configured to
generate a sensed temperature code from a temperature of the memory device, and
generate the digital temperature code by
calibrating the sensed temperature code based on a code ratio and an offset,
the code ratio being based on a ratio of a target full code to a difference between
a first temperature code corresponding to a first temperature,
a second temperature code corresponding to a second temperature, and
the offset corresponding to an operation mode of the memory cell array.

2. The memory device of claim 1, wherein
the digital temperature sensor is further configured to
calibrate the sensed temperature code based on the code ratio based on the operation mode being an erase mode or a program mode, and
calibrate the sensed temperature code based on the code ratio and the offset based on the operation mode being a read mode.

3. The memory device of claim 1, wherein the offset includes a noise offset having a different value according to the operation mode of the memory cell array.

4. The memory device of claim 3, wherein
the noise offset includes
a first noise offset corresponding to an erase mode,
a second noise offset corresponding to a program mode, and
a third noise offset corresponding to a read mode, and
the third noise offset is larger than the first noise offset or the second noise offset.

5. The memory device of claim 1, wherein the digital temperature sensor is further configured to calibrate the sensed temperature code based on a user offset defined by a user.

6. The memory device of claim 1, wherein
the target full code corresponds to a difference between
a first target code corresponding to the first temperature, and
a second target code corresponding to the second temperature.

7. The memory device of claim 1, wherein
the digital temperature sensor is further configured to
generate a first value by applying the offset to the first temperature code, and
generate the code ratio by dividing the target full code by a difference between the second temperature code and the first value.

8. The memory device of claim 7, wherein
the digital temperature sensor is further configured to
generate a second value by subtracting the first temperature code from the sensed temperature code, and
generate the digital temperature code by multiplying the code ratio by the second value.

9. The memory device of claim 7, wherein
the digital temperature sensor is further configured to
generate a second value by subtracting the first value from the sensed temperature code, and
generate the digital temperature code by multiplying the code ratio by the second value.

10. The memory device of claim 9, wherein
the digital temperature sensor is further configured to
generate the digital temperature code by applying a user offset to a result of multiplying the code ratio and the second value.

11. (canceled)

12. A memory device comprising:
a plurality of memories, each of the plurality of memories including,
a memory cell array including a plurality of memory cells; and
a digital temperature sensor configured to generate a digital temperature code with respect to the memory device,
wherein the digital temperature sensor is further configured to
generate a sensed temperature code from temperature of the memory device, and
generate the digital temperature code by
calibrating the sensed temperature code based on a code ratio and an offset,
the code ratio being based on a ratio of a target full code to a difference between
a first temperature code corresponding to a first temperature,
a second temperature code corresponding to a second temperature, and
the offset corresponding to an operation mode of the memory cell array, and
the plurality of memories are configured to respectively generate digital temperature codes by using different offsets.

13. The memory device of claim 12, wherein
the plurality of memories include
a first memory configured to communicate with a memory controller through a first channel, and
a second memory configured to communicate with the memory controller through a second channel,
the first memory includes a first digital temperature sensor configured to generate a first digital temperature code based on a first code ratio and a first offset,
the second memory includes a second digital temperature sensor configured to generate a second digital temperature code based on a second code ratio and a second offset, and
the first offset is different from the second offset.

14. The memory device of claim 13, wherein
the first offset includes a first noise offset having a different value according to an operation mode of a first memory cell array of the first memory, and
the second offset includes a second noise offset having a different value according to an operation mode of a second memory cell array of the second memory.

15. The memory device of claim 14, wherein
the first noise offset includes
an erase noise offset corresponding to an erase mode,
a program noise offset corresponding to a program mode, and
a read noise offset corresponding to a read mode, and
the read noise offset is larger than the erase noise offset or the program noise offset.

16. The memory device of claim 12, wherein the digital temperature sensor is further configured to calibrate the sensed temperature code based on a user offset defined by a user.

17. The memory device of claim 12, wherein
the target full code corresponds to a difference between
a first target code corresponding to the first temperature, and
a second target code corresponding to the second temperature.

18. The memory device of claim 12, wherein
the digital temperature sensor is further configured to
generate a first value by applying the offset to the first temperature code, and
generate the code ratio by dividing the target full code by a difference between the second temperature code and the first value.

19. The memory device of claim 18, wherein
the digital temperature sensor is further configured to
generate a second value by subtracting the first temperature code from the sensed temperature code, and
generate the digital temperature code by multiplying the code ratio by the second value.

20. (canceled)

21. A digital temperature sensor comprising:
a voltage generator configured to generate a reference voltage and a temperature voltage, the temperature voltage configured to vary with temperature;
an analog-to-digital converter configured to generate a sensed temperature code by performing an analog-to-digital conversion based on the reference voltage and the temperature voltage; and
a calibration logic configured to generate a digital temperature code by
calibrating the sensed temperature code based on a code ratio and an offset,
the code ratio being based on
a first temperature code corresponding to a first temperature,
a second temperature code corresponding to a second temperature, and
a target full code,
wherein the calibration logic is further configured to
generate a first value by applying the offset to the first temperature code, and generate the code ratio by dividing the target full code by a difference between the second temperature code and the first value, and
the target full code corresponds to a difference between
a first target code corresponding to the first temperature, and
a second target code corresponding to the second temperature.

22. The digital temperature sensor of claim 21, wherein the calibration logic is further configured to calibrate the sensed temperature code based on a user offset.

23. (canceled)

24. (canceled)

25. (canceled)
